(19) United States
(12) Patent Application Publication
(10) Pub. No.: US 2009/0084442 A1
(43) Pub. Date: Apr. 2, 2009

(54) Photovoltaic Cells and Manufacture Method

(75) Inventors: Hiroto Naito, Hitachi (JP); Naoki Yoshimoto, Hitachinaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi, Ltd.

(21) Appl. No.: 12/190,615

(22) Filed: Aug. 13, 2008

(30) Foreign Application Priority Data
Sep. 28, 2007 (JP) 2007-252953

(51) Int. Cl. H01L 31/0256; H01L 31/18

(52) U.S. Cl. 136/263; 438/82; 257/E31.003

(57) ABSTRACT

The present invention provides photovoltaic cells that stably increase photovoltaic conversion efficiency while restraining current leakage. The photovoltaic cells of the present invention include a transparent conductive layer formed on a light-permeable substrate, an organic semiconductor layer A covering the surface of the transparent conductive layer, a photovoltaic conversion layer in contact with the organic semiconductor layer, an organic semiconductor layer B in contact with the photovoltaic conversion layer, and a counter electrode in contact with the organic semiconductor layer B. In the photovoltaic cells, a patterned indented interlayer is formed at the interface between the organic semiconductor layer A and the photovoltaic conversion layer. With the patterned indented interlayer at the interface between the organic semiconductor layer A and the photovoltaic conversion layer, the interface between the organic semiconductor layer A and the photovoltaic conversion layer has a specific surface area 1.5 to 10 times as large as the interface between the transparent conductive layer and the organic semiconductor layer A.

### BACKGROUND OF THE INVENTION

1. Field of the Invention

The present invention relates to organic thin-film photovoltaic cells formed by stacking organic semiconductor layers, a photovoltaic conversion layer, and electrode layers, and more particularly, to photovoltaic cells that achieve high efficiency while maintaining high rectification, and a manufacture method for manufacturing the photovoltaic cells.

2. Description of the Related Art

Conventionally, solar cells of inorganic thin films made of Si, a GaAs compound, a CuInGaSe compound, or the like have been developed. However, those materials are costly, and an expensive device is necessary to carry out the procedures for manufacturing such solar cells. Furthermore, the energy required for the manufacture is large, and it is difficult to restrict the power generation cost to about the same level as a general electricity expense. In such circumstances, the future prospects are uncertain. To counter this problem, organic solar cells that can be easily manufactured without an expensive device have been vigorously developed recently.

Organic solar cells are roughly classified into: dye-sensitized solar cells formed with a porous TiO₂ film that is deposited on a visible-light permeable electrode and carries electrolyte-containing dyes with visible-light absorption properties, and a counter electrode; Schottky-barrier solar cells having a power generating mechanism that utilizes the Schottky barrier formed between a solid organic thin film and a metal thin film; and bi-layered pn-junction solar cells including a stack of a p-type organic semiconductor thin film and an n-type organic semiconductor thin film. The pn-junction solar cells are designed to increase the efficiency by providing a light absorption layer and a photovoltaic conversion layer at the pn interface. The pn-junction solar cells are further classified into: bulk hetero-junction types formed by dissolving a p-type organic semiconductor material (an acceptor) and an n-type organic semiconductor material (a donor) with a solvent, blending them in a solution state, and applying the resultant solution to the pn interface to form a thin film at the pn interface; and alternate absorption photovoltaic conversion layer types that can control the pn interface state by the nanometer level.

Among those organic solar cells, the dye-sensitized solar cells already have achieved 10% conversion efficiency. However, the dye-sensitized solar cells contain liquid electrolytes, and therefore, still have low reliability and stability. To achieve high efficiency, expensive materials such as Ru-based dyes or platinum electrodes are necessary, and the production costs cannot be lowered. If inexpensive materials are used, however, the conversion efficiency becomes much lower. Meanwhile, solar cells including an organic semiconductor of a perfect-solid polymer series might be manufactured by a coating technique at low costs. Particularly, the conversion efficiency of organic solar cells of a bulk hetero-junction type that are formed by blending conductive polymers and fullerene derivatives is higher than 3%, and the organic solar cells of the bulk hetero-junction type are being actively developed as solar cells that can achieve high efficiency at low costs.

FIG. 5 illustrates organic solar cells of a low-molecular series that have a p-type semiconductor layer 7 made of Cu phthalocyanine (CuPc) and an n-type semiconductor layer 8 made of a perylene derivative (PTCBI), both being formed through vapor deposition. In FIG. 5, reference numeral 9 indicates a transparent substrate made of glass or the like, reference numeral 10 indicates a transparent electrode, and reference numeral 11 indicates an electrode made of Ag or the like. In this structure, an internal electric field is induced in the vicinity of the pn junction between the p-type semiconductor layer 7 and the n-type semiconductor layer 8, and, when excitons generated in the p-type semiconductor layer 7 of CuPc due to light excitation move to the vicinity region of the pn junction, charge separations are caused by the internal electric field. As a result, the excitons are divided into electrons and holes, and are transported to the electrodes 10 and 11 opposite to each other. Thus, electric power is generated. The problems with this structure are that the distance the excitons in the p-type semiconductor layer 7 can move is short, and the internal field layer is thin. Therefore, it is necessary to form only thin films. This results in insufficient light absorption, and high conversion efficiency cannot be achieved.

Also, organic thin films have only short distances for carriers to be transported, and at present, approximately 100 nm is the upper limit of the distance that can be allowed for carriers. Therefore, if film thickness is increased, there is a high probability that carriers cannot reach the electrodes 10 and 11, and electrons and holes are recoupled to each other and disappear. This leads to a decrease in conversion efficiency. However, if the film thickness is small, light absorption becomes insufficient, and higher conversion efficiency cannot be expected.

As described above, organic semiconductors cannot be made thicker in general, having low carrier transport capability. With organic semiconductors, there are the problems of insufficient light absorption, insufficient carrier generation, and decreases in efficiency. There are two possible solutions to solve those problems. One of the two solutions is to increase the mobility of organic semiconductor materials, extend the carrier life, and increase the absorption rate, or to develop organic semiconductor materials with excellent characteristics. However, it is easy to predict that a very long research and development period and enormous costs will be necessary. The other one of the two solutions is a technique of achieving high efficiency while using the existing organic semiconductor materials. According to such a technique, the apparent effective area of the photovoltaic conversion layer is increased.

FIG. 4 shows organic thin-film solar cells having a photovoltaic conversion layer that has a patterned indented interlayer, and has an increased effective area, based on a reported example structure (see Jpn. J. Appl. Phys. Vol. 44, p.p. 1978-1981, by Y. Hashimoto, T. Umeda, et al., 2005). The solar cells shown in FIG. 4 include: an ITO (indium tin oxide) transparent electrode 13 having a patterned indented interlayer arranged at 5 μm intervals; an n-type semiconductor layer 14 that is made of C₆₀ or C₆₀:H₂Pc; a photovoltaic conversion layer 15; a p-type semiconductor layer 16 that is made of PAT6 (poly (3-hexylthiophene)); and an electrode 17 made of Al or Ag.

With the use of the patterned indented interlayer, light diffusion is caused, and the light absorption amount is increased. Not only that, the pn junction area to cause charge separations is made larger, and the number of carriers is increased with an increase in the number of exciton-charge separations. Thus, higher efficiency can be achieved with improvement of the photo-generating current.

However, thin-film defects are often caused in organic thin-film solar cells, and there is a large amount of leakage current in such organic thin-film solar cells. Therefore, there is a high probability that recoupling is caused in the thin films. Accordingly, if an organic thin film is formed on an electrode having a patterned indented interlayer, more defects are formed in the organic structure, and a larger amount of leakage current is generated than in a case where an organic thin film is formed on a smooth and flat substrate.

Meanwhile, if an organic thin film is deposited on ITO having a patterned indented interlayer, the indented surface may be smoothened out every time a film is stacked thereon, particularly in a case where the organic thin film is formed by a coating technique or the like. Therefore, the patterned indented interlayer is hardly maintained in the pn junction region, and it is difficult to achieve a desired effect. To counter this problem, the intervals between the patterned indented interlayer formed on the ITO need to be made longer, and the smoothening at the time of organic thin-film deposition needs to be restrained. However, if an organic thin film is deposited on the patterned indented surface arranged at longer intervals, a desired patterned indented interlayer cannot be formed in the photovoltaic conversion layer.

### SUMMARY OF THE INVENTION

The present invention has been made in view of these problems, and an object thereof is to provide photovoltaic cells and solar cells that stably increase photovoltaic conversion efficiency while restraining current leakage.

To achieve the above object, photovoltaic cells of the present invention are characterized by including: a transparent conductive layer formed on a light-permeable substrate; an organic semiconductor layer A covering the surface of the transparent conductive layer; a photovoltaic conversion layer in contact with the organic semiconductor layer; an organic semiconductor layer B in contact with the photovoltaic conversion layer; and a counter electrode in contact with the organic semiconductor layer B. In the photovoltaic cells, a patterned indented interlayer is formed at the interface between the organic semiconductor layer A and the photovoltaic conversion layer.

With the patterned indented interlayer at the interface between the organic semiconductor layer A and the photovoltaic conversion layer, the interface between the organic semiconductor layer A and the photovoltaic conversion layer has a specific surface area 1.5 to 10 times as large as the interface between the transparent conductive layer and the organic semiconductor layer A.

In accordance with the present invention, photovoltaic cells that stably increase photovoltaic conversion efficiency while restraining current leakage.

### BRIEF DESCRIPTION OF THE DRAWINGS

FIG. 1 illustrates a structure in accordance with an embodiment of the present invention;

FIGS. 2A through 2D are top views of examples of the structure of FIG. 1;

FIGS. 3A through 3D are cross-sectional views of examples of the structure of FIG. 1;

FIG. 4 illustrates the structure of organic solar cells including a conventional patterned indented interlayer; and

FIG. 5 illustrates the layer structure of conventional low-molecular organic solar cells.

### DESCRIPTION OF REFERENCE NUMERALS

1 translucent substrate
2 transparent conductive film
3 organic semiconductor layer A
4 photovoltaic conversion layer
5 organic semiconductor layer B
6 counter electrode

### DETAILED DESCRIPTION OF THE INVENTION

The following is a description of preferred embodiments of the present invention.

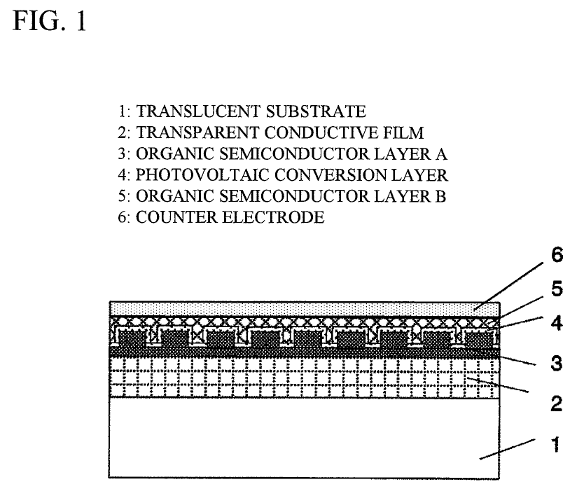

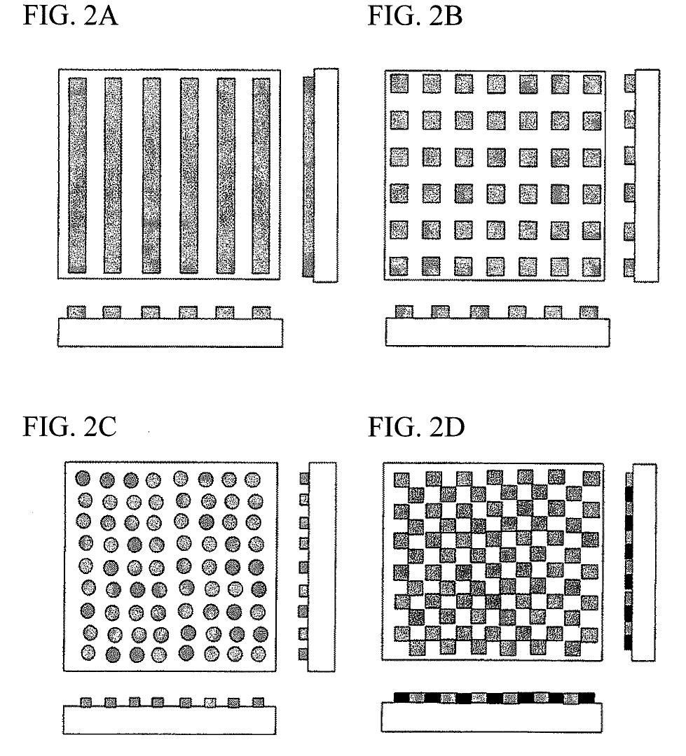

FIG. 1 is a cross-sectional view of an example of photovoltaic cells in accordance with an embodiment of the present invention. FIGS. 2A through 2D are top views of the photovoltaic cells of FIG. 1, illustrating examples of patterned indented interlayers that may be employed for the organic semiconductor layer A.

As shown in FIG. 1, the photovoltaic cells of this embodiment are formed by stacking a transparent conductive film 2, an organic semiconductor layer 3, a photovoltaic conversion layer 4, an organic semiconductor layer 5, and a counter electrode 6 in this order on a translucent substrate 1. The organic semiconductor layer 3 has a patterned indented interlayer, and the photovoltaic conversion layer 4 is formed in conformity with the patterned indented interlayer. The organic semiconductor layer 5 is formed on the patterned indented surface of the photovoltaic conversion layer 4. Here, the organic semiconductor layer 3 serves as a hole transport layer or an electron transport layer, and the organic semiconductor layer 5 has the characteristics opposite to those of the organic semiconductor layer 3. The counter electrode 6 is an electrode made of Al or the like.

The translucent substrate 1 is made of a translucent material such as glass. The transparent conductive film 2 is a visible-light permeable conductive film deposited by a thin-film formation technique, such as a sputtering technique, the CVD technique, the sol-gel technique, or the dipping-pyrolysis process. The transparent conductive film 2 may be made of indium tin oxide (ITO), F-doped zinc oxide (ZnO), tin oxide (SnO₂), or the like, but the materials that can be used for the transparent conductive film 2 are not limited to those materials. Since those oxide semiconductor thin films have hydrophobicity, the organic semiconductor layer 3 cannot be deposited on any of them. Therefore, the transparent conductive film 2 is exposed to UV over a predetermined period of time, to form a hydrophilic base such that the contact angle of the thin-film surface with respect to the liquid is 10 degrees or less when one drop of pure water is dropped onto the thin-film surface. In this manner, the hydrophilic base is formed to allow easy deposition of an organic semiconductor layer.

FIGS. 2A through 2D are top views showing examples of patterned indented interlayers that may be formed in the organic semiconductor layer 3. The difference in height between the patterned indented interlayers is 50 nm. The specific surface area with respect to the flat plane is larger, as the aspect ratio is higher or the difference in height is larger, or the interval of patterned indented interlayer is shorter. The example shown in FIG. 2A is of a line type, and the line width and the space width are both 50 nm. With this patterned indented interlayer, the surface area is expected to increase approximately three times. The example shown in FIG. 2B is a structure having small square convexities. Each of the convexities is 50 nm×50 nm in size, and the space width is also 50 nm. With this patterned indented interlayer, the surface area is expected to increase approximately three times. The example shown in FIG. 2C is a structure having cylindrical convexities. The diameter of each of the convexities is 50 nm, and the space between each two cylindrical convexities is 50 nm. With this patterned indented interlayer, the surface area is expected to increase approximately 2.5 times. The example shown in FIG. 2D is a checkered structure having 50-nm square convexities even at the spaces shown in FIG. 2B. With this patterned indented interlayer, the surface area is expected to increase approximately five times.

By forming a patterned indented interlayer in the organic semiconductor layer 3, the specific surface area of the interface between the organic semiconductor layer 3 and the photovoltaic conversion layer 4 is made 1.5 to 10 times as large as that of the interface between the transparent conductive layer 2 and the organic semiconductor layer 3. By forming the photovoltaic conversion layer 4 in conformity with the patterned indented interlayer of the organic semiconductor layer 3, the photovoltaic conversion layer 4 also has a patterned indented interlayer. Accordingly, like the interface between the organic semiconductor layer 3 and the photovoltaic conversion layer 4, the specific surface area of the interface between the photovoltaic conversion layer 4 and the organic semiconductor layer 5 is made 1.5 to 10 times as large as that of the interface between the transparent conductive layer 2 and the organic semiconductor layer 3.

In the case where the organic semiconductor layer 3 is a hole transport layer, conductive polymers such as PEDOT/PSS may be deposited by a coating technique or the like. After that, calcination is performed several times to form a thin film.

The present invention is characterized in that the transparent conductive film 2 does not have a patterned indented interlayer so as to reduce leakage current, and that the energy conversion efficiency is enhanced by forming a patterned indented interlayer in the organic semiconductor layer 3 on the transparent conductive film 2. In the patterned indented interlayer, the distance between each two neighboring concavities or convexities is made 100 nm or less. For example, when the intervals are 100 nm or less, the organic semiconductor film 3 has 50-nm thick concave portions and 100-nm thick convex portions. The patterned indented interlayer is produced by forming a pattern having concavities and convexities at 50-nm intervals on the surface of the organic semiconductor layer 3 by a technique such as the nano-imprint technique. Particularly, in the case of a PEDOT/PSS material, the upper limit of the carrier diffusion distance is approximately 100 nm, and carrier deactivation might be caused if the thickness is larger than 100 nm. If the thickness is smaller than 30 or 50 nm, on the other hand, an increase in leakage current is caused. To prevent carrier recoupling and an increase in leakage current, it is preferable that the difference between the interface between the transparent conductive film 2 and the organic semiconductor layer 3, and the uppermost surface of the organic semiconductor layer 3 in the film deposition direction is 30 to 50 nm at a minimum, and 80 to 100 nm at a maximum.

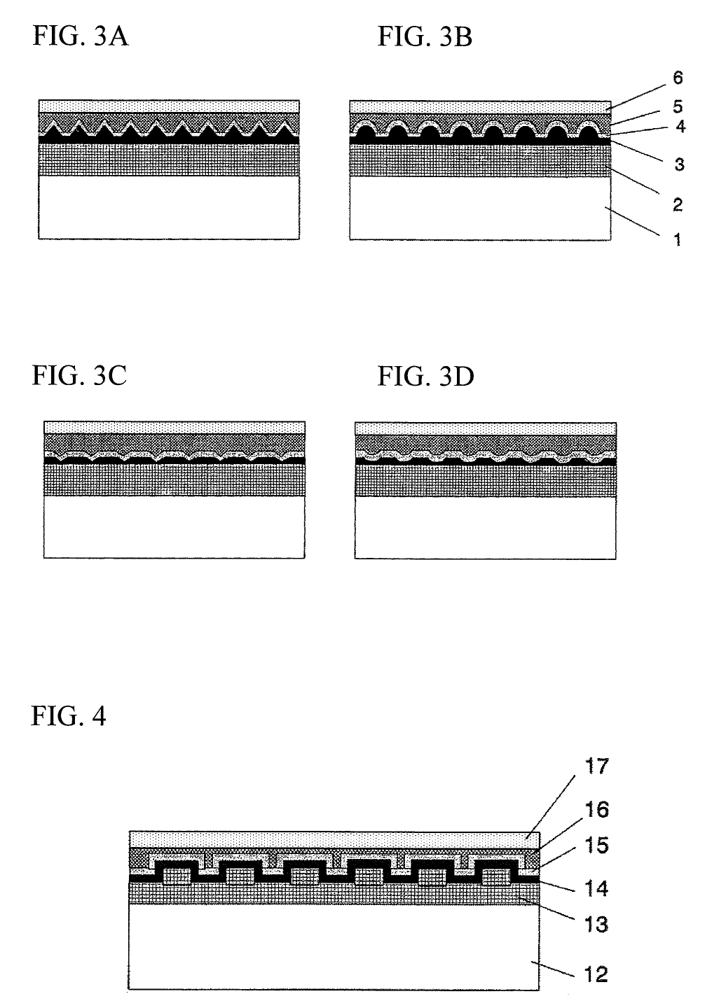

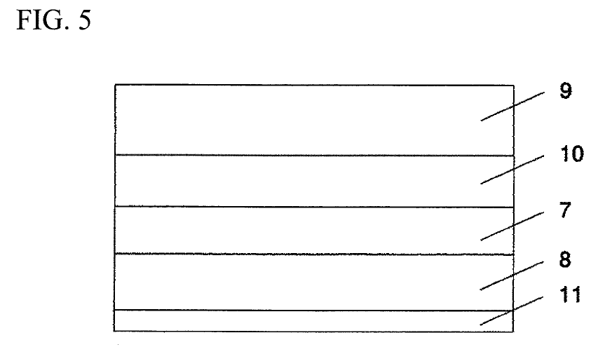

FIGS. 3A through 3D are cross-sectional views of samples each having a patterned indented interlayer. It is preferable that the cross-sectional areas of the concavities and convexities of those samples are substantially the same, and that the concavities and convexities are arranged at substantially regular intervals. The shapes of the cross sections are not particularly restricted to the shapes shown in FIGS. 3A through 3D, but may be any planar shapes such as circles, rectangles, or triangles.

To deposit the photovoltaic conversion layer, it is effective to use an alternate adsorption technique, if the organic semiconductor layer A is of PEDOT/PSS. By the alternate adsorption technique, cationic species existing on the film surface are used, and an anionic organic matter is potentially adsorbed and deposited. After that, anionic species are used, and a cationic organic semiconductor is again adsorbed so as to deposit the photovoltaic conversion layer. Other than that, the vacuum vapor deposition technique is desirable, being able to cause film deposition in conformity with a patterned indented interlayer. In any case, to form the photovoltaic conversion layer, the film deposition should be performed in conformity with the patterned indented interlayer of the organic semiconductor layer A.

After the photovoltaic conversion layer is deposited while the patterned indented interlayer is maintained, the organic semiconductor layer B is deposited. In a case where the organic semiconductor layer A is a hole transport layer, the organic semiconductor layer B is an electron transport layer formed by carrying out thin-film deposition. The electron transport layer may be made of a fullerene derivative, and should preferably have a film thickness of approximately 30 nm from the upper limit of the carrier diffusion length.

A metal electrode is deposited as the uppermost layer, and the film formation for this is normally carried out by the vacuum vapor deposition technique or the sputtering technique. The metal material employed here should preferably be a material that has a work function not very different from that of the organic semiconductor layer B, and can be in ohmic contact with the organic semiconductor layer B.

In the solar cells of organic thin films formed in the above manner, when the light absorption layer absorbs light and is electronically excited, excitons are generated. Due to the internal field of the light absorption layer, or due to the charge separation at the interfaces with the adjacent hole transport layer and electron transport layer, the excitons become dissociated into holes and electrons. The holes move through the hole transport layer and reach the substrate electrode. Accordingly, the substrate electrode adjacent to the hole transport layer serves as the positive electrode. The electrons move through the electron transport layer, and reach the counter electrode. Accordingly, the counter electrode adjacent to the electron transport layer serves as the negative electrode. As a result, a potential difference is caused between the substrate electrode and the counter electrode. The smooth movement of holes and electrons is realized by the gradient of the highest occupied electron level of the light absorption layer and the substrate electrode via the hole transport layer, or the gradient of the lowest emptied electron level of the light absorption layer and the counter electrode via the electron transport layer, as described earlier. As the light absorption layer absorbs light, holes and electrons are generated. The holes reach the substrate electrode, and the electrons move through the electron transport layer to reach the counter electrode.

The photovoltaic cells of this embodiment form a stereoscopic structure, that is, a three-dimensional structure having a patterned indented interlayer in the organic semiconductor layer A deposited on the transparent electrode. Accordingly, the specific surface area becomes larger, and the pn junction area is increased so as to facilitate an increase of the number of generated carriers. Also, the organic semiconductor layer that has a three-dimensional structure while keeping a predetermined distance from the transparent electrode is covered with the photovoltaic conversion layer. Accordingly, the film thickness of the organic semiconductor film can be readily controlled, and leakage current can be restrained as recoupling hardly occurs. Thus, the energy conversion efficiency of the photovoltaic cells can be improved.

### First Embodiment

Next, embodiments of the present invention are described, (with reference to FIG. 1, whenever necessary).

A substrate electrode 1 is a translucent glass substrate formed by depositing ITO (indium tin oxide) as a transparent electrode (hereinafter referred to as the ITO substrate). The ITO substrate is subjected to ultrasonic cleaning with the use of a toluene solution, an acetone solution, and an ethanol solution for 10 to 15 minutes, respectively. The ITO substrate is then washed with pure water or ultrapure water, and is dried with a nitrogen gas.

An UV-ozone treatment is then carried out with the use of an UV irradiation device such as an ozone cleaner, so as to form a hydrophilic base on the substrate surface. In this manner, a hydrophilic substrate on which an organic semiconductor layer can be readily deposited is formed.

A mixed solution containing PEDOT/PSS to be a hole transport layer and ethylene glycol at the mixing ratio of 5:1 is applied by a spin coating technique onto the ITO thin-film surface of the ITO substrate subjected to the hydrophilic treatment. The spin-on coating is performed at the initial speed of 400 rpm for 10 seconds, and at the final speed of 3000 rpm for 100 seconds, so as to deposit a film of approximately 100 nm in thickness. After that, 15-hour, 70° C. calcination is performed in the atmosphere at atmospheric pressure. Lastly, 1-hour, 140° C. calcination is performed in high vacuum, so as to form a thin film.

At this point, while heating is performed at a temperature almost the same as the transition temperature of PEDOT, a nano-imprint metal mold having the indented pattern shown in FIG. 2D is pressed against the thin film, and the thin film is cooled at the same time. In this manner, a patterned indented interlayer is formed. The patterned indented interval is 50 nm. The smallest film thickness of the patterned indented surface of the PEDOT is 30 to 50 nm, and the largest film thickness is 80 to 100 nm.

To form a thin film to be a light absorption layer by an alternate adsorption technique, a PPV solution and a PSS solution are prepared. An adjustment is made with ultrapure water so that the pre-PPV becomes 1 mmol, and a PH adjustment is made with NaOH so that the PH becomes 8 to 9. After that, an adjustment is made with ultrapure water so that the PSS becomes 10 mmol. In this manner, solutions are prepared.

Since anionic species exist in the PEDOT/PSS surface, the PEDOT/PSS surface is immersed in a cationic PPV solution, and is then immersed in an anionic PSS solution. In this manner, a thin film is formed using alternate adsorption films. Here, the adsorption time is 5 minutes, the drying time is 4 minutes and 30 seconds. Prior to the immersion in the solutions of two different kinds, the immersion (rinse) time in ultrapure water is 3 minutes, and the drying time is 4 minutes and 30 seconds. This procedure is repeated 5 times, so that the desired film thickness is achieved, and the next deposition of an electron transport layer is made easier through the termination with cationic PPV. Since the photovoltaic conversion layer is formed by the adsorption technique like a LB technique, adsorption is performed in conformity with the patterned indented interlayer.

The electron transport layer may be made of fullerene (C60) or the like. Fullerene is mixed along with a polymer material such as polystyrene (PS) into an o-dichlorobenzene solution. The mixing ratio here is: o-dichlorobenzene:C60:PS=217:4:1. A solution adjustment is performed by stirring the mixed solution sufficiently with ultrasonic wave.

After the solution adjustment, a thin film is formed by a coating technique with the use of a 0.45 μm filter or the like. A 30 nm film is formed at the initial speed of 400 rpm for 10 seconds, and at the final speed of 3000 rpm for approximately 100 seconds. Calcination is then performed in vacuum at 100° C. for 2 hours, so as to form a thin film.

Lastly, a metal material such as aluminum is deposited to form an electrode by the vacuum vapor deposition technique. A suitable amount of aluminum wires is placed on a tungsten board, and an aluminum thin film of approximately 50 nm in film thickness is formed in high vacuum of approximately 2×10⁻⁶ Torr at the deposition rate of 2 to 3 [Å/s], with the substrate temperature being room temperature and the substrate rotation speed being approximately 30 rpm. Thus, the photovoltaic cells are produced.

### Second Embodiment

Photovoltaic cells are produced in the same manner as in the first embodiment, except that a nano-imprint metal mold having the indented pattern shown in FIG. 2A is used to form the patterned indented interlayer of the hole transport layer.

### Third Embodiment

The photovoltaic conversion layer is formed by a simultaneous vapor deposition technique, instead of the thin film formation by the alternate adsorption technique used to form the photovoltaic conversion layer of the first embodiment. By the simultaneous vapor deposition technique, a p-type organic semiconductor film and an n-type organic semiconductor film are formed simultaneously through vacuum vapor deposition. Other than that, the same procedures as those of the first embodiment are carried out to form photovoltaic cells.

### Fourth Embodiment

The electron transport layer is formed by a vapor deposition technique with the use of fullerene particles for sublimation purification, instead of the technique of forming a coated fullerene thin film to be the electron transport layer of the first embodiment. In this embodiment, fullerene particles for sublimation purification are placed on a tungsten board in a vacuum vapor deposition device, and fullerene is deposited by a resistance heating technique, to form the electron transport layer. Other than the formation of the electron transport layer, the same procedures as those of the first embodiment are carried out to form photovoltaic cells.

### Fifth Embodiment

The photovoltaic conversion layer is formed by the simultaneous vapor deposition technique of the third embodiment in which a p-type organic semiconductor film and an n-type organic semiconductor film are formed simultaneously through vacuum vapor deposition, and the electron transport layer is formed by the vacuum vapor deposition technique of the fourth embodiment that involves fullerene particles for sublimation purification. Other than the formation of the photovoltaic conversion layer and the electron transport layer, the same procedures as those of the first embodiment are carried out to form photovoltaic cells.

### Sixth Embodiment

A first electrode is formed as a thin film on a substrate by a technique such as a metal vapor deposition technique, and fullerene to form the electron transport layer is coated or vapor-deposited on the first electrode. The patterned indented interlayer shown in FIG. 2D is then formed in the electron transport layer by a nano-imprint technique. The photovoltaic conversion layer is formed on the electron transport layer having the patterned indented interlayer by an alternate adsorption technique. The hole transport layer made of PEDOT or the like is then formed on the photovoltaic conversion layer by a coating technique or the like. Lastly, an oxide translucent conductor is formed to produce photovoltaic cells.

### COMPARATIVE EXAMPLE 1

Photovoltaic cells are formed by carrying out the same procedures as those of the first embodiment, except that a patterned indented interlayer is not formed on the hole transport layer. In the same manner as in the first embodiment, the photovoltaic conversion layer, the electron transport layer, and the electrode are formed on the hole transport layer that has a PEDOT/PSS film thickness of 80 to 100 nm and does not have a patterned indented interlayer.

### COMPARATIVE EXAMPLE 2

Photovoltaic cells are formed by carrying out the same procedures as those of the first embodiment, except that the hole transport layer is formed with a PEDOT/PSS film that has a patterned indented surface of both 30 nm or less in the smallest film thickness and 80 to 100 nm in the largest film thickness.

### COMPARATIVE EXAMPLE 3

Photovoltaic cells are formed by carrying out the same procedures as those of the first embodiment, except that the hole transport layer is formed with a PEDOT/PSS film that has a patterned indented surface of both 30 to 50 nm in the smallest film thickness and 100 nm or larger in the largest film thickness.

### COMPARATIVE EXAMPLE 4

Photovoltaic cells are formed by carrying out the same procedures as those of the fifth embodiment, except that the photovoltaic conversion layer has a bulk hetero structure formed by a spin coating technique.

### COMPARATIVE EXAMPLE 5

Solar cells of organic thin films are formed by carrying out the same procedures as those of the sixth embodiment, except that a patterned indented interlayer is not formed on the electron transport layer, and that the electron transport layer remains without a patterned indented interlayer.

Pseudo-sunlight (AM 1.5) is emitted from a solar simulator on the stack-type organic solar cells of the first through sixth embodiments and Comparative Examples 1 through 6 produced in the above described manners. The output characteristics are evaluated to obtain the results shown in Tables 1 and 2.

TABLE 1

| | First | Second | Third | Fourth | Fifth | Sixth |
|---|---|---|---|---|---|---|
| | Embodiment | Embodiment | Embodiment | Embodiment | Embodiment | Embodiment |
| Short-Circuit | 3.0 | 1.6 | 2.8 | 3.1 | 3.2 | 2.9 |
| Current | | | | | | |
| [Ma/Cm²] | | | | | | |
| Open Voltage | 0.80 | 0.79 | 0.80 | 0.79 | 0.78 | 0.78 |
| [V] | | | | | | |
| Form Factor | 0.51 | 0.54 | 0.52 | 0.52 | 0.53 | 0.51 |
| Conversion | 1.23 | 0.68 | 1.16 | 1.27 | 1.18 | 1.15 |
| Efficiency | | | | | | |
| [%] | | | | | | |

TABLE 2

| | Comparative | Comparative | Comparative | Comparative | Comparative |
|---|---|---|---|---|---|
| | Example 1 | Example 2 | Example 3 | Example 4 | Example 5 |
| Short-Circuit | 0.85 | 1.2 | 1.3 | 2.6 | 0.80 |
| Current | | | | | |
| [Ma/Cm²] | | | | | |
| Open Voltage | 0.83 | 0.81 | 0.79 | 0.8 | 0.78 |
| [V] | | | | | |
| Form Factor | 0.35 | 0.28 | 0.40 | 0.38 | 0.41 |
| Conversion | 0.24 | 0.27 | 0.41 | 1.06 | 0.26 |
| Efficiency | | | | | |
| [%] | | | | | |

As can be seen from Tables 1 and 2, increases in short-circuit current density contribute to increases in conversion efficiency in the photovoltaic cells having the patterned indented interlayers. The PEDOT/PSS specific surface areas of the first and second embodiments are five times as large as the PEDOT/PSS specific surface area of Comparative Example 1. Accordingly, it is considered that the increased light absorption rate leads to an increase in current value.

In Comparative Example 2, the smallest PEDOT/PSS film thickness is 30 nm or less, and the form factors seem to decrease due to the influence of leakage current. In Comparative Example 3, the largest film thickness of the patterned indented interlayer is 100 nm or larger. As a result, the carrier transport rate becomes lower, and it is considered that the efficiency also becomes lower.

The photovoltaic cells of the third embodiment have the photovoltaic conversion layer formed through simultaneous vapor deposition. The photovoltaic cells of the fourth embodiment have the transport layer formed by a vapor deposition technique. In both embodiments, the efficiency is higher than in the Comparative Example 4. The photovoltaic cells of the fifth embodiment have the photovoltaic conversion layer and the electron transport layer both formed by a vapor deposition technique, and the fifth embodiment achieves the same results as those of the first embodiment.

The photovoltaic cells of Comparative Example 4 have the deposited photovoltaic conversion layer of a bulk hetero type. Since the photovoltaic conversion layer is deposited by a coating technique, the surface of the photovoltaic conversion layer is smoothened, which leads to a decrease in light absorption rate. As a result, the photovoltaic conversion efficiency becomes lower.

The photovoltaic cells of the sixth embodiment have the structure that is opposite to the structure of the first embodiment, with the electron transport layer having a patterned indented interlayer. Compared with the photovoltaic cells of Comparative Example 5, which has the same film structure as that of the sixth embodiment but does not have a patterned indented interlayer, the sixth embodiment achieves much higher photovoltaic conversion efficiency. This is because the specific surface area increased with the concavities and convexities leads to the increase in light absorption rate, which in turn contributes to the increase in conversion efficiency.

What is claimed is:

1. Photovoltaic cells comprising:
a transparent conductive layer;
an organic semiconductor layer A that is formed on the transparent conductive layer;
a photovoltaic conversion layer that is formed on the organic semiconductor layer A;
an organic semiconductor layer B that is formed on the photovoltaic conversion layer; and
an electrode that is formed on the organic semiconductor layer B,
wherein a patterned indented interlayer is formed at an interface between the organic semiconductor layer A and the photovoltaic conversion layer.

2. The photovoltaic cells according to claim 1, wherein the organic semiconductor layer A includes a hole transport layer or an electron transport layer.

3. The photovoltaic cells according to claim 1, wherein the organic semiconductor layer A is a hole transport layer while the organic semiconductor layer B is an electron transport layer, or the organic semiconductor layer A is an electron transport layer while the organic semiconductor layer B is a hole transport layer.

4. The photovoltaic cells according to claim 1, wherein the distance between each two neighboring concave portions or convex portions of the patterned indented interlayer is 100 nm or less.

5. The photovoltaic cells according to claim 1, wherein the photovoltaic conversion layer is formed of an organic semiconductor having photosensitivity for light of 300 nm to 1000 nm in wavelength.

6. The photovoltaic cells according to claim 1, wherein the shortest distance from an interface between the transparent conductive layer and the organic semiconductor layer A to the interface between the organic semiconductor layer A and the photovoltaic conversion layer is 30 to 50 nm.

7. The photovoltaic cells according to claim 1, wherein the photovoltaic conversion layer is formed in conformity with the patterned indented interlayer.

8. The photovoltaic cells according to claim 1, wherein surfaces of both the organic semiconductor layer A and the organic semiconductor layer B in contact with the photovoltaic conversion layer each have a patterned indented interlayer.

9. The photovoltaic cells according to claim 1, wherein the interface between the organic semiconductor layer A and the photovoltaic conversion layer has a specific surface area 1.5 to 10 times as large as an interface between the transparent conductive layer and the organic semiconductor layer A.

10. The photovoltaic cells according to claim 8, wherein an interface between the photovoltaic conversion layer and the organic semiconductor layer B has a specific surface area 1.5 to 10 times as large as an interface between the transparent conductive layer and the organic semiconductor layer A.

11. Solar cells of pn-junction type comprising:
a transparent conductive layer;
an organic semiconductor layer A that is deposited on the transparent conductive layer;
a photovoltaic conversion layer that is formed on the organic semiconductor layer A;
an organic semiconductor layer B that is deposited on the photovoltaic conversion layer; and
an electrode that is formed on the organic semiconductor layer B,
wherein a patterned indented interlayer is formed on a surface of the organic semiconductor layer A in a film deposition direction, and an interface between the organic semiconductor layer A and the photovoltaic conversion layer having a specific surface area 1.5 to 10 times as large as an interface between the transparent conductive layer and the organic semiconductor layer A.

12. A photovoltaic cells manufacture method comprising the steps of:
depositing an organic semiconductor layer A on a transparent electrode formed by depositing a transparent conductive layer;
forming a patterned indented interlayer on a surface of the organic semiconductor layer A;
forming a photovoltaic conversion layer on the surface of the organic semiconductor layer A;
depositing an organic semiconductor layer B on a surface of the photovoltaic conversion layer; and
forming an electrode on a surface of the organic semiconductor layer B.

13. The photovoltaic cells manufacture method according to claim 12, wherein the photovoltaic conversion layer is formed in conformity with the patterned indented interlayer of the organic semiconductor layer A.

14. The photovoltaic cells manufacture method according to claim 13, wherein the photovoltaic conversion layer is formed by an alternate adsorption stacking technique.

15. The photovoltaic cells manufacture method according to claim 12, wherein the patterned indented interlayer is formed on the surface of the organic semiconductor layer A by an imprint technique.
